(19) United States
(12) Patent Application Publication
(10) Pub. No.: US 2011/0272774 A1
(43) Pub. Date: Nov. 10, 2011

(54) SEMICONDUCTOR DEVICE AND METHOD FOR MANUFACTURING THE SAME

(75) Inventor: Keiichi ITAGAKI, Kanagawa (JP)

(73) Assignee: Renesas Electronics Corporation

(21) Appl. No.: 13/101,718

(22) Filed: May 5, 2011

(30) Foreign Application Priority Data
May 6, 2010 (JP) 2010-106317

(51) Int. Cl. H01L 31/14

(52) U.S. Cl. 257/437; 438/98; 257/E31.097

(57) ABSTRACT

A semiconductor device which has a low-profile laminate structure including an interlayer insulating film and includes an easily formed alignment mark, and a method for manufacturing the semiconductor device. The semiconductor device includes a photoelectric transducer formed in a semiconductor substrate, a stopper film in a mark area, a first interlayer insulating film formed over the stopper film and photoelectric transducer, a first metal interconnect, and a second interlayer insulating film. A through hole which penetrates the first and second interlayer insulating films and reaches the stopper film is made and a first concave is made in the upper surface of a conductive layer in the through hole. A second concave to serve as an alignment mark is made in a second metal interconnect above the first concave.

### CROSS-REFERENCE TO RELATED APPLICATIONS

The disclosure of Japanese Patent Application No. 2010-106317 filed on May 6, 2010 including the specification, drawings and abstract is incorporated herein by reference in its entirety.

### BACKGROUND

The present invention relates to a semiconductor device and a method for manufacturing the same and more particularly to a semiconductor device including a photoelectric transducer such as a photodiode and a method for manufacturing the same.

For image sensors used in digital cameras, particularly single-lens reflex digital cameras, improvement in the sensitivity to external light is desirable. For example, when a photodiode is used in an image sensor, the top of the photodiode is usually covered by a laminate structure in which thin films including interlayer insulating films are stacked.

In making this laminate structure, a thin film formed at a later step is patterned as desired using a previously formed layer as a mark for alignment. Here, the mark for alignment is, for example, a concave made in a portion of a metal layer. For example, Japanese Unexamined Patent Publication No. Hei 3 (1991)-138920 discloses a semiconductor device in which such an alignment mark is made.

### SUMMARY

In order for an image sensor to increase its sensitivity to external light which it receives, it is desirable to decrease the thickness (height) of the laminate structure lying over, for example, a photodiode as a constituent of the image sensor. By decreasing the thickness of the interlayer insulating film as a constituent of the laminate structure, the possibility that the intensity of light entering the photodiode from outside decreases due to the interlayer insulating film can be reduced.

However, when the height of the laminate structure is decreased, the depth of a concave made in the upper surface of the metal film filled in a hole penetrating the laminate structure is also decreased. Therefore, if the height of the laminate structure is decreased, it will be difficult to make a clear alignment mark in the hole as a concave in a sufficiently thick metal film. If the alignment mark concave is not deep enough and not clear, there will be difficulty in alignment at the exposure step of the later photoengraving process.

On the other hand, if the height of the laminate structure is increased, it will be easy to make a concave which is deep enough and sufficiently clear but the intensity of light entering the photodiode from outside will decrease. This may result in deterioration in the sensitivity to external light entering the photodiode.

In the semiconductor device described in Japanese Unexamined Patent Publication No. Hei 3 (1991)-138920, the hole for an alignment mark reaches the surface of the semiconductor substrate. Thus the alignment mark hole is deep and the thickness of the metal interconnect film on the sidewall of the alignment mark hole largely varies in the radial direction of the hole. This causes deterioration in alignment accuracy.

The present invention has been made in view of the above problem and an object thereof is to provide a semiconductor device which has a low-profile or thin laminate structure including an interlayer insulating film and ensures high alignment accuracy, and a method for manufacturing the same.

According to one aspect of the present invention, a semiconductor device is configured as follows. The semiconductor device includes: a semiconductor substrate having a main surface; a photoelectric transducer formed in the semiconductor substrate; a stopper film formed over the main surface of the semiconductor substrate; a first interlayer insulating film formed over the stopper film and over the photoelectric transducer; a first metal interconnect formed over the first interlayer insulating film; and a second interlayer insulating film formed so as to cover the first metal interconnect and the photoelectric transducer. A hole which penetrates the first and second interlayer insulating films and reaches the stopper film is made. The device further includes an in-hole conductive layer formed along a sidewall and a bottom wall of the hole with a first concave in an upper surface thereof and a second metal interconnect formed over the in-hole conductive layer and the second interlayer insulating film, in which a second concave to serve as an alignment mark is located just above the first concave and in an upper surface thereof.

According to a second aspect of the present invention, a method for manufacturing a semiconductor device includes the following steps. First, a photoelectric transducer is formed in a semiconductor substrate having a main surface. A metal interconnect is formed over the main surface of the semiconductor substrate. An interlayer insulating film is formed over the metal interconnect and over the photoelectric transducer. A hole reaching the metal interconnect is made in the interlayer insulating film. A conductive layer for filling the hole is formed. The upper surface of the conductive layer is selectively removed to make the upper surface of the conductive layer recessed from an upper surface of the interlayer insulating film. A metal layer is formed over the upper surface of the conductive layer and over the upper surface of the interlayer insulating film so as to make a concave to serve as an alignment mark, in the upper surface of the metal layer just above the conductive layer.

According to the first aspect of the invention, the depth of the hole in which an alignment mark is formed is equivalent to the sum of the thickness of the first interlayer insulating film and that of the second interlayer insulating film. A sufficiently deep concave is made in the upper surface of the in-hole conductive layer formed along the sidewall and bottom wall of this deep hole. Therefore, the semiconductor device can have a clear alignment mark with a sufficient depth which is formed above the concave.

In the manufacturing method according to the second aspect of the invention, the upper surface of the conductive layer filling the hole is recessed from the upper surface of the interlayer insulating film. A concave to serve as an alignment mark is made above the recessed upper surface of the conductive layer. As a consequence, a clear alignment mark with a sufficient depth is formed.

### BRIEF DESCRIPTION OF THE DRAWINGS

FIG. 1 is a schematic plan view showing a semiconductor device according to a first embodiment of the present invention in an on-wafer state;

FIG. 2 is a schematic plan view showing the area encircled by dotted line II in FIG. 1 in enlarged form;

FIG. 3 is a schematic plan view showing a chip corresponding to the area encircled by dotted line III in FIG. 2 in enlarged form;

FIG. 4 is a schematic plan view showing an example of an alignment mark in the first embodiment;

FIG. 5 is a schematic sectional view taken along the line V-V in FIG. 4;

FIG. 6 is a schematic plan view showing another example of an alignment mark in the first embodiment which is different from the one shown in FIG. 4;

FIG. 7 is a schematic sectional view taken along the line VII-VII in FIG. 6;

FIG. 8 is a schematic plan view showing another example of an alignment mark in the first embodiment which is different from the ones shown in FIGS. 4 and 6;

FIG. 9 is a schematic sectional view taken along the line IX-IX in FIG. 8;

FIG. 10 is a schematic sectional view showing the structure of the semiconductor device according to the first embodiment;

FIG. 11 is a schematic sectional view showing the first step of the method for manufacturing the semiconductor device according to the first embodiment;

FIG. 12 is a schematic sectional view showing the second step of the method for manufacturing the semiconductor device according to the first embodiment;

FIG. 13 is a schematic sectional view showing the third step of the method for manufacturing the semiconductor device according to the first embodiment;

FIG. 14 is a schematic sectional view showing the fourth step of the method for manufacturing the semiconductor device according to the first embodiment;

FIG. 15 is a schematic sectional view showing the fifth step of the method for manufacturing the semiconductor device according to the first embodiment;

FIG. 16 is a schematic sectional view showing the sixth step of the method for manufacturing the semiconductor device according to the first embodiment;

FIG. 17 is a schematic sectional view showing the seventh step of the method for manufacturing the semiconductor device according to the first embodiment;

FIG. 18 is a schematic sectional view showing the eighth step of the method for manufacturing the semiconductor device according to the first embodiment;

FIG. 19 is a schematic sectional view showing the ninth step of the method for manufacturing the semiconductor device according to the first embodiment;

FIG. 20 is a schematic sectional view showing the tenth step of the method for manufacturing the semiconductor device according to the first embodiment;

FIG. 21 is a schematic sectional view showing the eleventh step of the method for manufacturing the semiconductor device according to the first embodiment;

FIG. 22 is a schematic sectional view showing the twelfth step of the method for manufacturing the semiconductor device according to the first embodiment;

FIG. 23 is a schematic sectional view showing the thirteenth step of the method for manufacturing the semiconductor device according to the first embodiment;

FIG. 24 is a schematic sectional view showing the fourteenth step of the method for manufacturing the semiconductor device according to the first embodiment;

FIG. 25A is a schematic sectional view showing a conductive layer formed in the mark area in the first embodiment and FIG. 2B is a schematic sectional view showing a conductive layer as a comparative example for the first embodiment;

FIG. 26 is a photo showing the cross section of a mark suitable for use as an alignment mark together with item numbers corresponding to the dimensional data shown in Table 1;

FIG. 27 is a photo showing the cross section of a mark unsuitable for use as an alignment mark together with item numbers corresponding to the dimensional data shown in Table 1;

FIG. 28 is a schematic sectional view showing a variation of the semiconductor device according to the first embodiment in which the stopper film is different from the one shown in FIG. 10;

FIG. 29 is a schematic sectional view showing a variation of the semiconductor device according to the first embodiment in which the conductive layer is different from the one shown in FIG. 28;

FIG. 30 is a schematic sectional view showing a variation of the semiconductor device according to the first embodiment in which the stopper film is different from the ones shown in FIGS. 10 and 28;

FIG. 31 is a schematic sectional view showing a variation of the semiconductor device according to the first embodiment in which the conductive layer is different from the one shown in FIG. 30;

FIG. 32 is a schematic sectional view showing a step subsequent to the step shown in FIG. 18 in the first embodiment in the method for manufacturing a semiconductor device according to a second embodiment of the present invention;

FIG. 33 is a schematic sectional view showing a step subsequent to the step shown in FIG. 32 in the method for manufacturing a semiconductor device according to the second embodiment;

FIG. 34 is a schematic sectional view showing a step subsequent to the step shown in FIG. 33 in the method for manufacturing a semiconductor device according to the second embodiment;

FIG. 35 is a schematic sectional view showing a step subsequent to the step shown in FIG. 34 in the method for manufacturing a semiconductor device according to the second embodiment; and

FIG. 36 is a schematic sectional view showing a step subsequent to the step shown in FIG. 35 in the method for manufacturing a semiconductor device according to the second embodiment.

### DETAILED DESCRIPTION

Next, the preferred embodiments of the present invention will be described referring to the accompanying drawings.

### First Embodiment

First, a semiconductor device according to the first embodiment in an on-wafer state is described below.

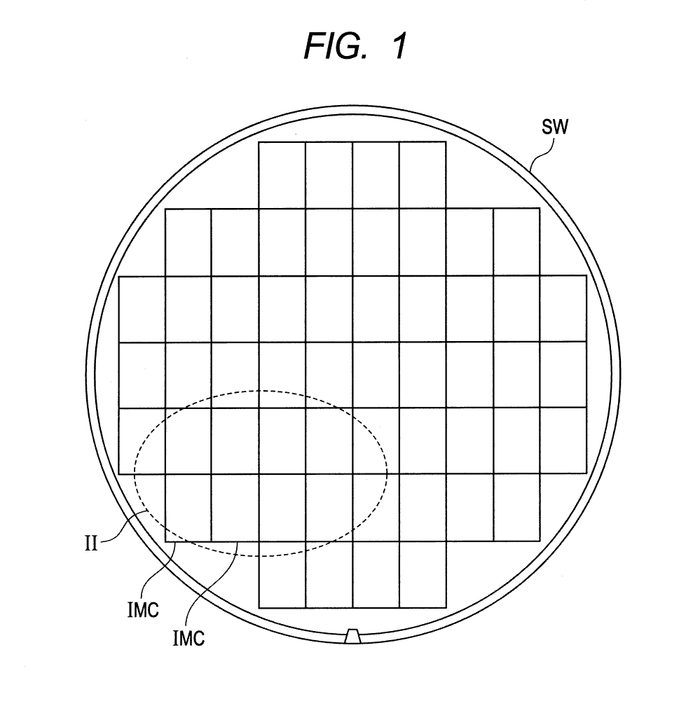

Referring to FIG. 1, a plurality of chip regions IMC for image sensors are formed on a semiconductor wafer SW. The chip regions IMC each have a rectangular planar shape and are arranged in a matrix pattern.

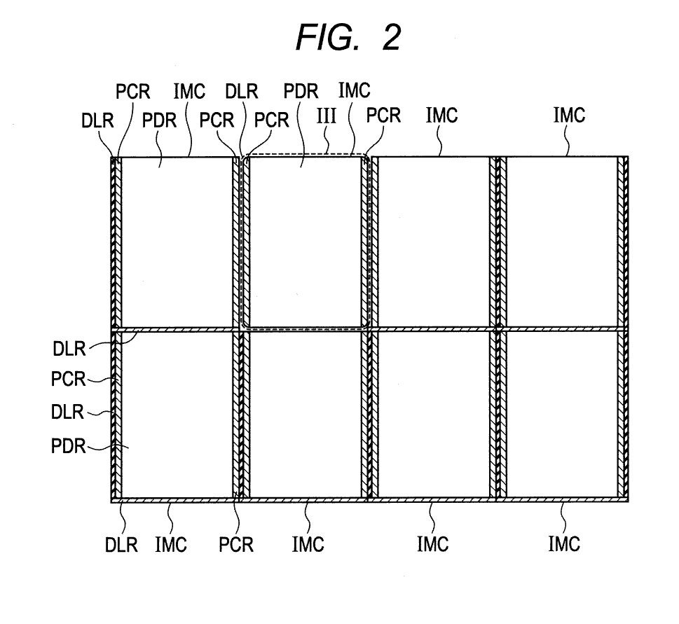

Referring to FIG. 2, each of the chip regions IMC has a region PDR for the formation of a photoelectric transducer such as a photodiode and a region PCR for the formation of a peripheral circuit for controlling the photodiode. The formation region PCR is provided on both sides of the formation region PDR. A dicing line region DLR is formed between chip regions IMC. Alignment marks are arranged in the dicing line region DLR.

The semiconductor wafer SW is divided into plural semiconductor chips by dicing the semiconductor wafer SW along the dicing line region DLR.

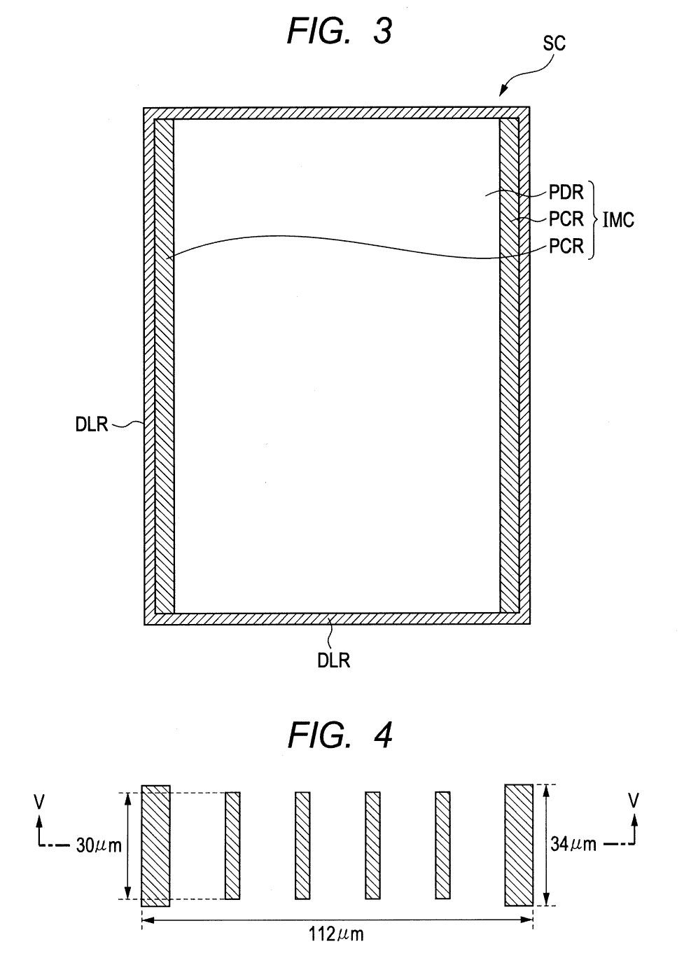

Next, the semiconductor device according to the first embodiment in the form of a chip will be described. Referring to FIG. 3, a semiconductor chip SC has a rectangular planar shape and includes a photodiode formation region PDR, peripheral circuit formation regions PCR, and a dicing line region DLR. Among the alignment marks in the dicing line region DLR, some are cut by dicing and the others remain uncut.

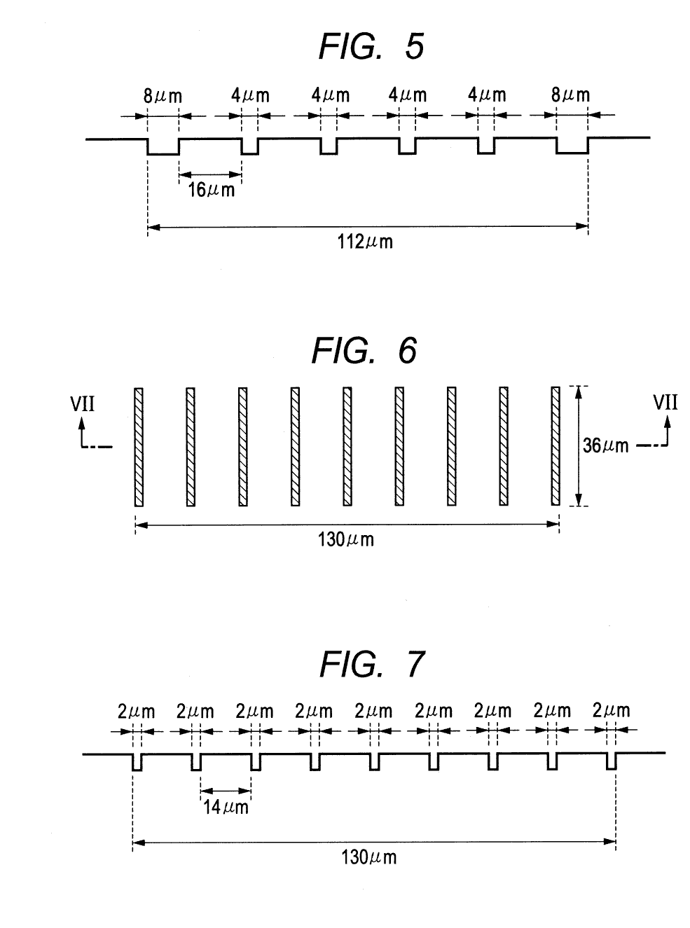

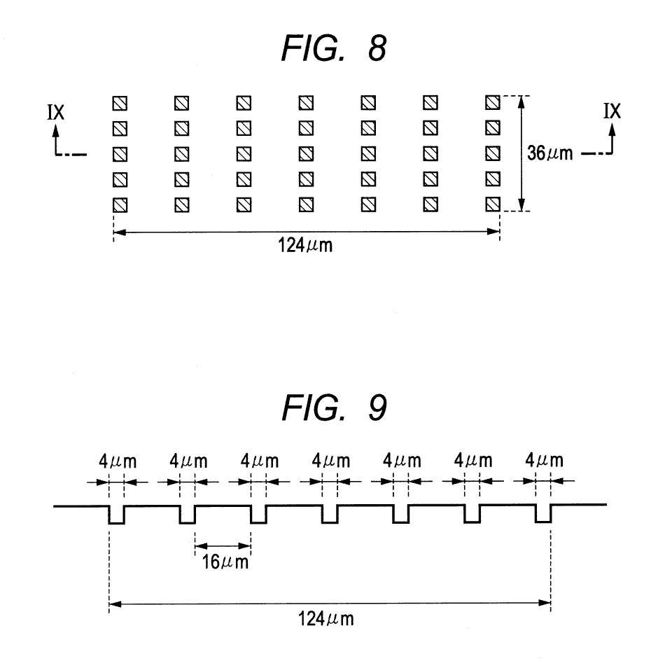

An example of the alignment marks is shown in FIGS. 4 and 5, in which each alignment mark is long with a length between 30 μm and 34 μm in a plan view and a width between 4 μm and 8 μm and the spacing between neighboring alignment marks is 16 μm. Another example is shown in FIGS. 6 and 7, in which each alignment mark is long with a length of 36 μm in a plan view and a width of 2 μm and the spacing between neighboring alignment marks is 14 μm. A further example is shown in FIGS. 8 and 9, in which each alignment mark is 4 μm square in a plan view and the spacing between neighboring alignment marks is 16 μm. In some cases, recesses or concaves in the upper surface of a film are used as such alignment marks.

Next, an image sensor both in an on-wafer state and in the form of a chip and its alignment mark will be described.

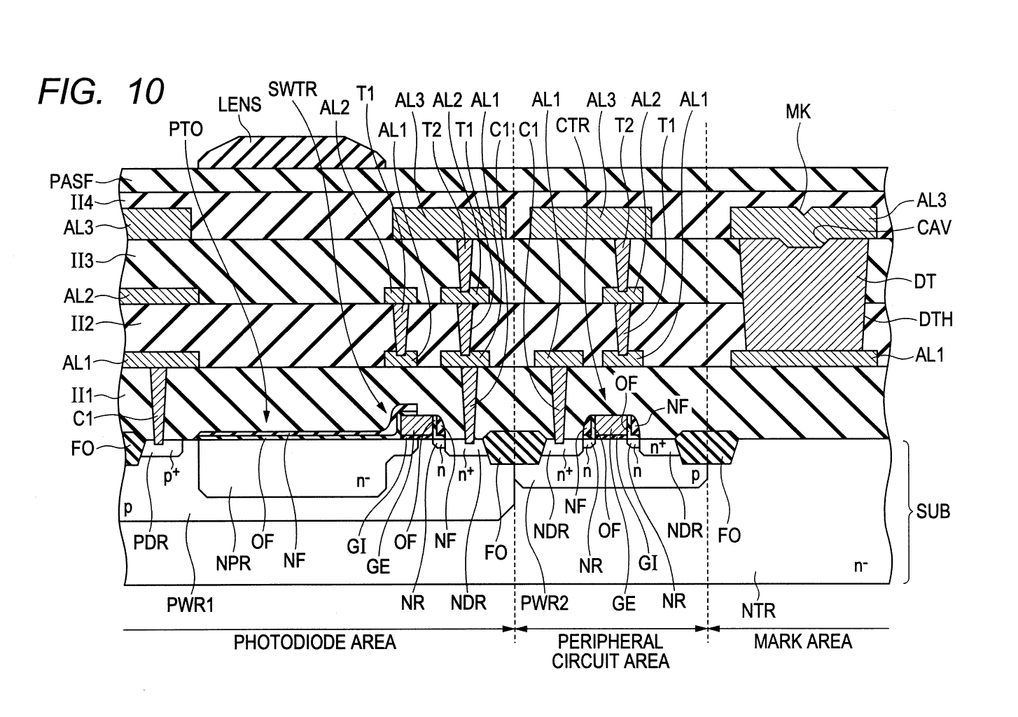

Referring to FIG. 10, the image sensor in this embodiment has a photodiode PTO in a photodiode area and a control transistor CTR in a peripheral circuit area. A concave MK as an alignment mark is formed in a mark area.

More specifically, the image sensor is formed in an n-region NTR of a silicon semiconductor substrate SUB. The photodiode area, peripheral circuit area and alignment mark area are separated from each other by a field oxide film FO formed over the surface of the semiconductor substrate SUB.

The photodiode PTO includes a p-type well region PWR1 and an n-type impurity region NPR. The p-type well region PWR1 is formed in the photodiode area in the surface of the semiconductor substrate SUB. The n-type impurity region NPR is formed in the p-type well region PWR1 in the surface of the semiconductor substrate SUB and makes a p-n junction with the p-type well region PWR1.

The photodiode area also includes a MIS (Metal Insulator Semiconductor) transistor such as a switching transistor SWTR. Particularly the switching transistor SWTR includes a pair of source/drain regions NPR and NR/NDR, a gate insulating film GI, and a gate electrode GE. The pair of n-type source/drain regions NPR and NR/NDR are spaced and arranged in the p-type well region PWR1 in the surface of the semiconductor substrate SUB. NPR as one of the pair of n-type source/drain regions NPR and NR/NDR is integral with the n-type impurity region NPR of the photodiode PTO and electrically coupled with it. NR/NDR as the other of the pair of source/drain regions NPR and NR/NDR includes an n+ impurity region NDR as a high concentration region and an n-type impurity region NR as an LDD (Lightly-Doped Drain). The gate electrode GE is formed over the surface of the semiconductor substrate SUB between the pair of source/drain regions NPR and NR/NDR through the gate insulating film GI.

In addition, a p+ impurity region PDR for coupling with an overlying interconnect is formed in the surface of the semiconductor substrate SUB in the p-type well region PWR1.

A laminated anti-reflection coating including a silicon oxide film OF and a silicon nitride film NF is formed over the surface of the semiconductor substrate SUB in a way to cover the photodiode PTO. One end of this anti-reflection coating OF/NF lies over one sidewall of the gate electrode GE. A sidewall insulating layer including a silicon oxide film OF and a silicon nitride film NF as a residue of the anti-reflection coating OF/NF is formed on the other sidewall of the gate electrode GE.

For example, a p-type well region PWR2 is formed in the surface of the semiconductor substrate SUB in the peripheral circuit area. A control element for controlling the operation of plural photodiodes PTO is formed in this p-type well region PWR2 and the control element includes, for example, a MIS transistor CTR.

The MIS transistor CTR includes a pair of n-type source/drain regions NR/NDR, a gate insulating film GI, and a gate electrode GE. The pair of n-type source/drain regions NR/NDR are spaced and formed in the surface of the semiconductor substrate SUB. The pair of n-type source/drain regions NR/NDR each include an n-type impurity region NDR as a high concentration region and an n-type impurity region NR as an LDD.

The gate electrode GE is formed over the surface of the semiconductor substrate SUB between the pair of n-type source/drain regions NR/NDR through a gate insulating film GI. A sidewall insulating layer including an oxide film OF and a nitride film NF as an anti-reflection coating residue is formed on the sidewall of the gate electrode GE.

The material of the gate electrode GE of each MIS transistor in the photodiode area and peripheral circuit area may be impurity-doped polycrystal silicon or a metal such as TiN.

In the photodiode area, peripheral circuit area, and alignment mark area (dicing line region), an interlayer insulating film II1 is formed over the surface of the semiconductor substrate SUB in a way to cover the above elements (photodiode PTO, MIS transistors SWTR and CTR). In the photodiode area and peripheral circuit area, a patterned first metal interconnect AL1 is formed over the interlayer insulating film II1. This first metal interconnect AL1 is electrically coupled, for example, with the p+ impurity region PDR or n+ impurity region NDR through a contact C1 filling a contact hole of the interlayer insulating film II1.

In the alignment mark area, a stopper film AL1 is formed over the interlayer insulating film II1. For example, this stopper film AL1 is formed by separating the same metal film as used for the metal interconnect AL1 using ordinary photoengraving and etching techniques and may be made of aluminum (Al) or copper (Cu).

An interlayer insulating film II2 is formed over the interlayer insulating film II1 in a way to cover the metal interconnect AL1 and stopper film AL1. In the photodiode area and peripheral circuit area, a patterned second metal interconnect AL2 is formed over the interlayer insulating film II2. This second metal interconnect AL2 is electrically coupled with the first metal interconnect AL1 through a conductive layer T1 filling a through hole of the interlayer insulating film II2.

An interlayer insulating film II3 is formed over the interlayer insulating film II2 in a way to cover the metal interconnect AL2. In the photodiode area and peripheral circuit area, a patterned third metal interconnect AL3 is formed over the interlayer insulating film II3. This third metal interconnect AL3 is electrically coupled with the second metal interconnect AL2 through a conductive layer T2 filling a through hole of the interlayer insulating film II3.

In the alignment mark area, a through hole DTH is made in the interlayer insulating films II2 and II3, penetrating the interlayer insulating films II2 and II3 and reaching the stopper film AL1. A conductive layer (in-hole conductive layer) DT is formed in the through hole DTH along the sidewall and bottom wall of the through hole DTH. This conductive layer DT is, for example, made of tungsten (W). A concave (first concave) CAV is made in the upper surface of the conductive layer DT.

A metal film for an alignment mark (second metal interconnect) AL3 is formed over the upper surface of the conductive layer DT and over the upper surface of the interlayer insulating film II3. A concave (second concave) MK to serve as an alignment mark is made in the upper surface of the alignment mark metal film AL3 and just above the concave CAV of the conductive layer DT. For example, this alignment mark metal film AL3 is formed from the same metal film as used for the metal interconnects AL3 in the photodiode and peripheral circuit areas using ordinary photoengraving and etching techniques and may be made of aluminum or copper.

An interlayer insulating film 114 is formed over the interlayer insulating film II3 in a way to cover the metal interconnects AL3 in the photodiode and peripheral circuit areas and alignment mark metal film AL3. A passivation film PASF is formed over the interlayer insulating film 114. A condenser lens LENS is placed over the passivation film PASF and just above the photodiode PTO. This condenser lens LENS is used to collect light and throw the light on the photodiode PTO.

The interlayer insulating films II1, II2, II3, and II4 are, for example, made of silicon oxide or a material which is different from the metal stopper film AL1 in terms of etching selectivity (for example, etching selectivity in etching the interlayer insulating film II2 or II3 for the formation of the through hole DTH).

The sidewall of the through hole DTH forms a continuous surface in the direction from the upper surface of the interlayer insulating film II3 to the stopper film AL1 without any level difference in the boundary between the interlayer insulating films II2 and II3. In other words, in the cross section shown in FIG. 10, the sidewall of the through hole DTH extends linearly from the upper surface of the interlayer insulating film II3 to the surface of the stopper film AL1. A barrier metal film may be formed on the sidewall and bottom wall of the through hole DTH, though not shown.

The concave MK shown in the sectional view of FIG. 10 is tapered downward (triangular). However, if the width (horizontal dimension in FIG. 10) of the concave CAV is increased, the lower width will be almost equal to the upper width as shown in FIGS. 5, 7, and 9.

FIG. 10 shows one photodiode PTO and one switching element SWTR in the photodiode area, one control transistor CTR in the peripheral circuit area, and one concave MK in the mark area. Actually, however, more than one photodiode PTO and more than one switching element SWTR are spaced and arranged in each of the individual chips as shown in FIG. 3.

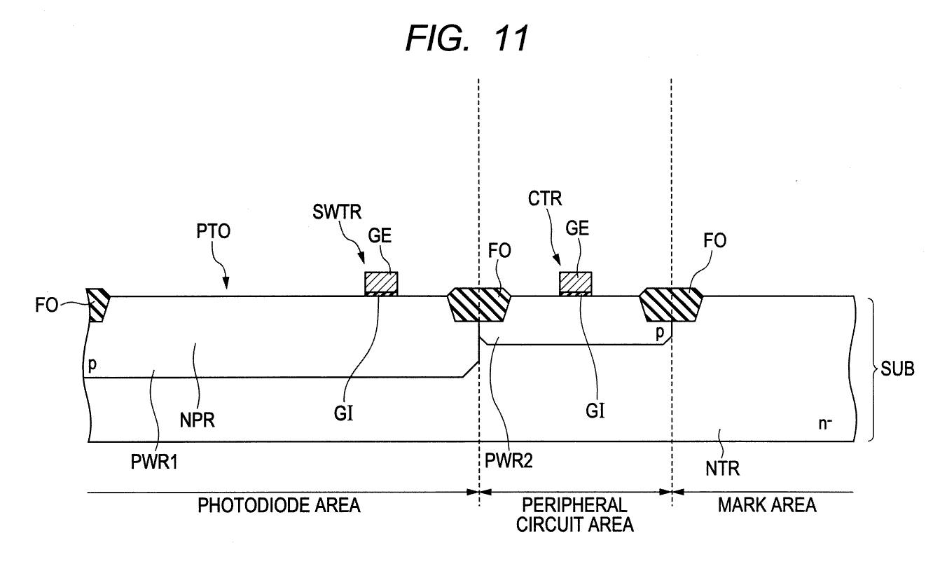

Next, the method for manufacturing the semiconductor device according to the first embodiment as shown in FIG. 10 will be explained referring to FIGS. 11 to 23.

Referring to FIG. 11, a semiconductor substrate SUB, made of a semiconductor material (silicon, germanium, etc) which depends on the wavelength of light in use, is prepared. An n-region NTR as an n− epitaxial growth layer is formed in the surface of the semiconductor substrate SUB. Then, p-type well regions PWR1 and PWR2 are formed in the photodiode area and peripheral circuit area respectively. Field oxide films FO are formed in the boundary between the photodiode and peripheral circuit areas and the boundary between the peripheral circuit and mark areas. The field oxide films FO electrically isolate the formation regions of the photodiode, peripheral circuit and mark areas from each other.

Then, a gate insulating film GI and a gate electrode GE are formed in desired places. The concrete procedure is as follows. Agate insulating film is formed over the main surface of the semiconductor substrate SUB, for example, by thermal oxidation. A polycrystal silicon film or the like to form a gate electrode is deposited over the gate insulating film.

Then, the gate insulating film and polycrystal silicon or the like are patterned so that a gate insulating film GI and a gate electrode GE are formed as shown in FIG. 11.

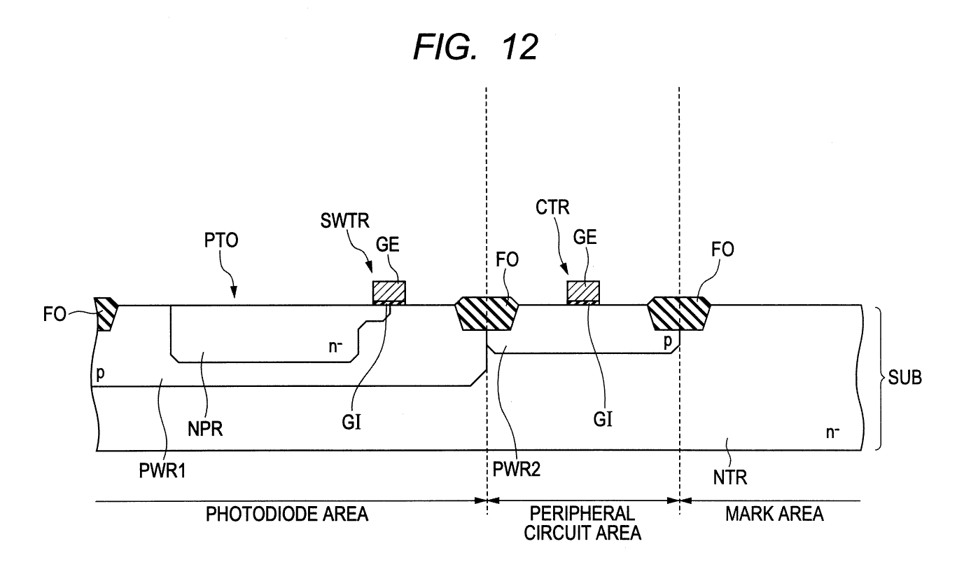

Referring to FIG. 12, an n-type impurity region NPR is formed inside the p-type well region PWR1 of the photodiode area using ordinary photoengraving and ion implantation techniques. A photodiode PTO, including the p-type well region PWR1 and n-type impurity region NPR, is thus formed.

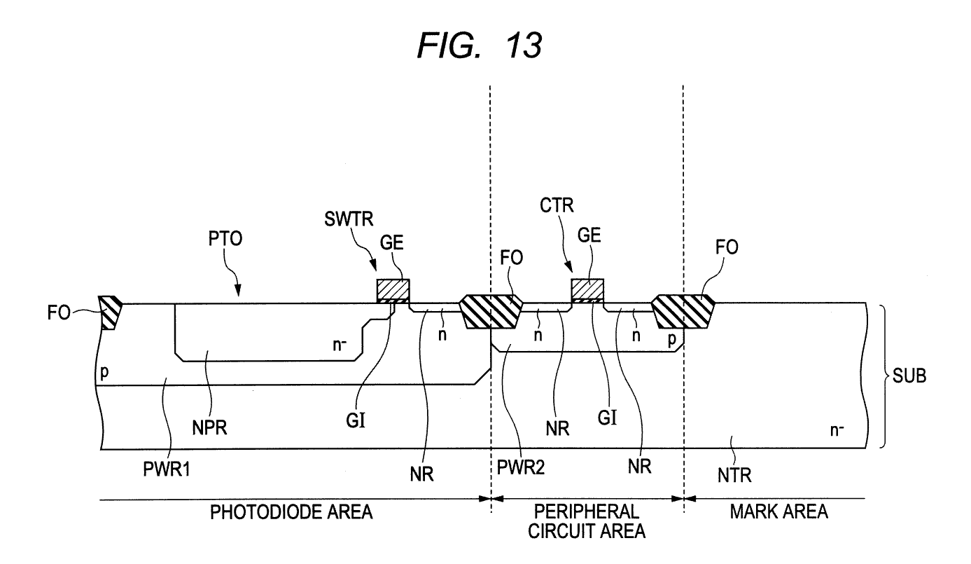

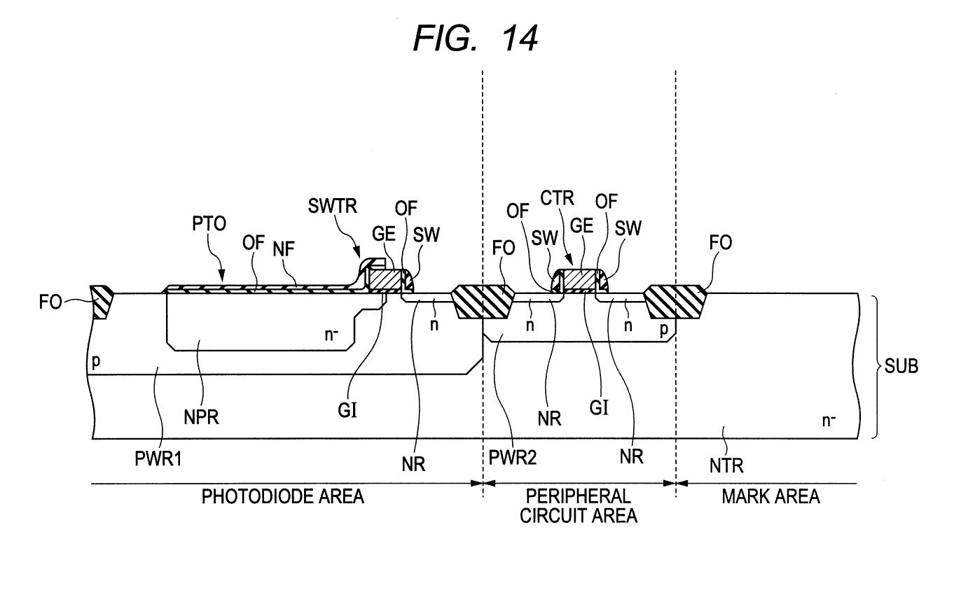

Referring to FIG. 13, an n-type region NR to become an LDD is formed in the surface of the semiconductor substrate SUB inside each of the p-type well regions PWR1 and PWR2 of the photodiode area using ordinary photoengraving and ion implantation techniques.

Referring to FIG. 14, for example, a silicon oxide film OF and a silicon nitride film NF are deposited one upon the other in order all over the surface of the semiconductor substrate SUB. Then, the silicon oxide film OF and silicon nitride film NF are patterned in a way to cover at least the photodiode PTO using ordinary photoengraving and etching techniques so that an anti-reflection coating including the silicon oxide film OF and silicon nitride film NF is made.

Also, by etching the silicon oxide film OF and silicon nitride film NF, a sidewall insulating layer as a residue of the anti-reflection coating is formed on the sidewall of each gate electrode GE.

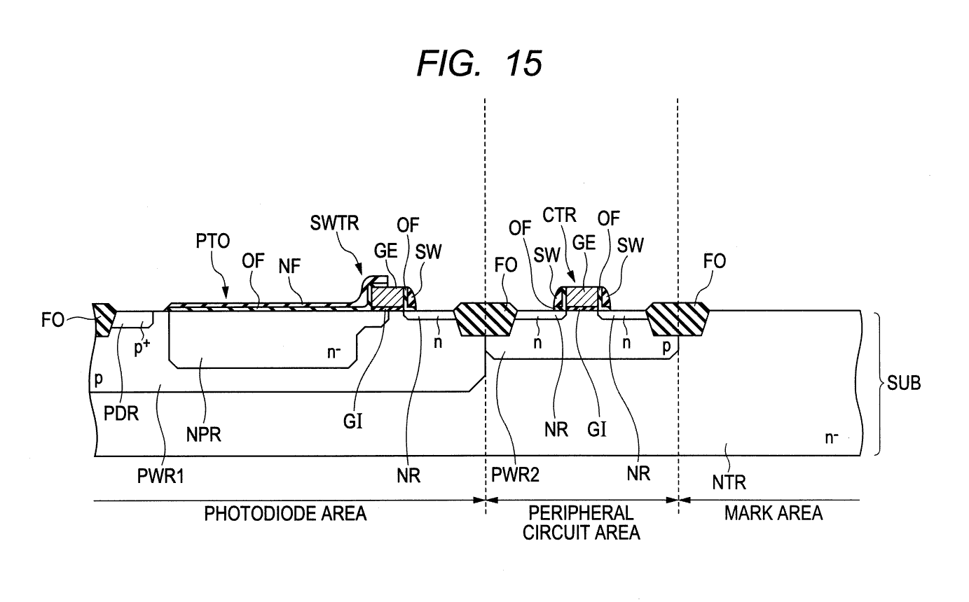

Referring to FIG. 15, a p+ region PDR is formed in a prescribed place of the p-type well region PWR1 using ordinary photoengraving and ion implantation techniques.

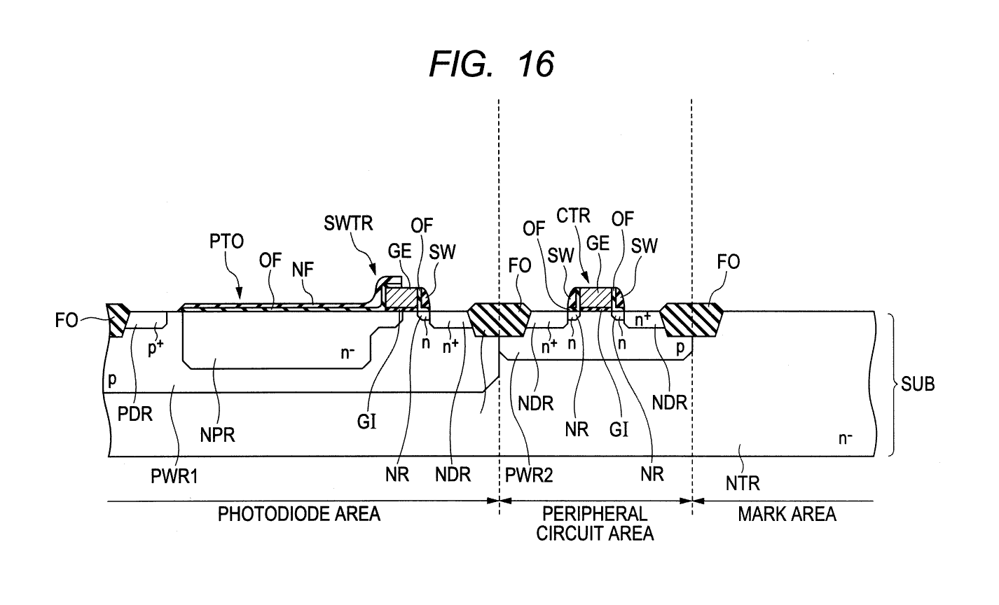

Referring to FIG. 16, an n-type region NDR is formed in a prescribed place of each of the photodiode and peripheral circuit areas using ordinary photoengraving and ion implantation techniques. The n-type region NDR is an n+ region which has a higher impurity concentration than the n-type region NR.

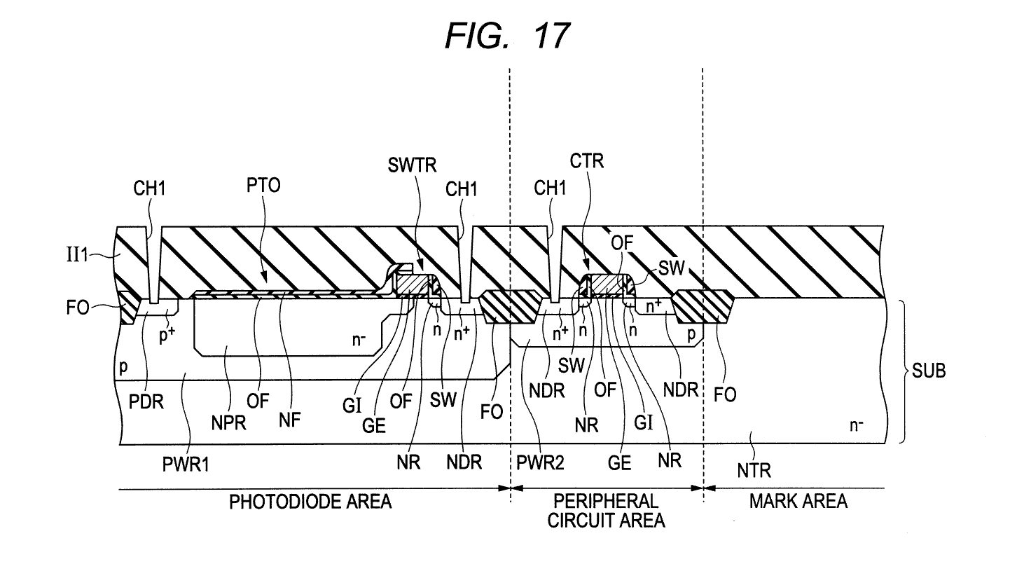

Referring to FIG. 17, an interlayer insulating film II1 as a silicon oxide film is formed by CVD (Chemical Vapor Deposition). Then the interlayer insulating film II1 is polished by CMP (Chemical Mechanical Polishing) so that its upper surface is flattened. Furthermore, contact holes CH1 are made in the interlayer insulating film II1 using ordinary photoengraving and etching techniques in a way to reach the n-type region NDR and p-type region PDR.

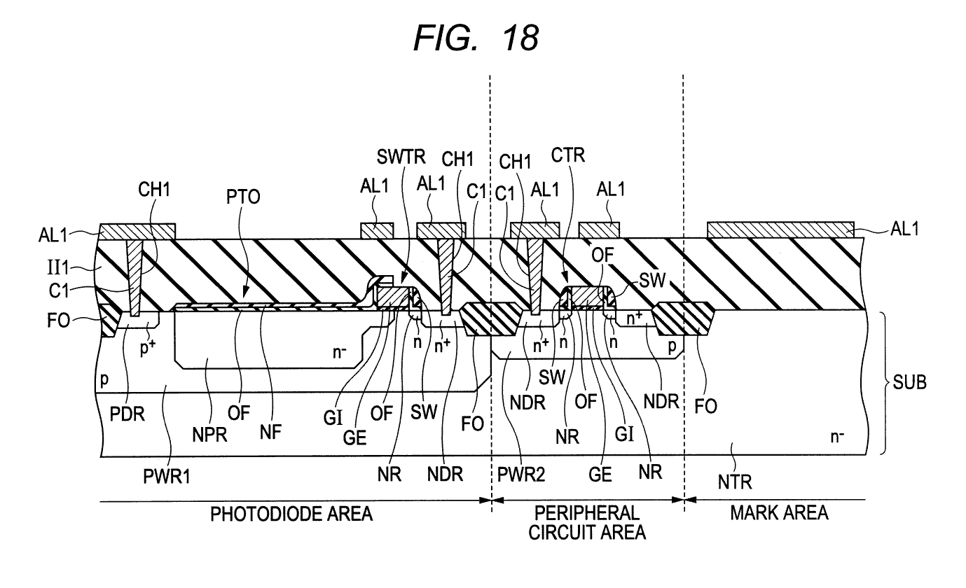

Referring to FIG. 18, a conductive film C1, for example, made of tungsten is filled in each contact hole CH1. For example, CVD is employed for this process and a thin tungsten film is also formed over the interlayer insulating film II1. The thin tungsten film over the interlayer insulating film II1 is removed by CMP. Then, a thin film, for example, made of aluminum is formed over the interlayer insulating film II1, for example, by sputtering. Then, using ordinary photoengraving and etching techniques, a metal interconnect AL1, for example, made of aluminum is formed in each of the photodiode and peripheral circuit areas and a stopper film AL1, for example, made of aluminum is formed in the mark area.

The metal interconnects AL1 in the photodiode and peripheral circuit areas are electrically coupled to the n-type regions NDR and p-type region PDR through the contacts C1.

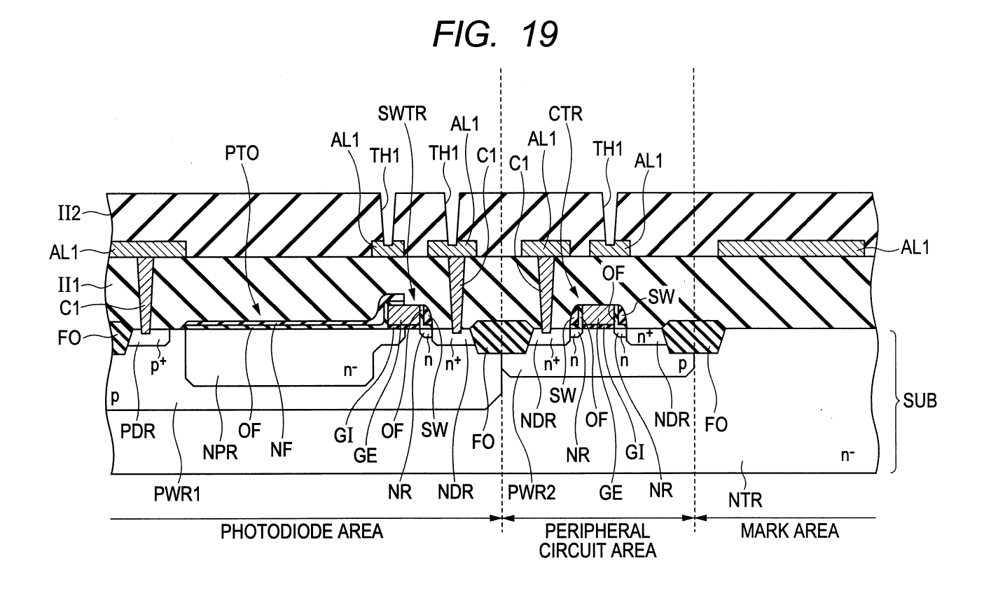

Referring to FIG. 19, an interlayer insulating film II2 is formed over the interlayer insulating film II1, metal interconnects AL1 and stopper film AL1 and through holes TH1 are made in desired places (above the metal interconnects AL1). The interlayer insulating film II2 and through holes TH1 are formed with the same procedure as the interlayer insulating film II1 and contact holes CH1. Since the etching selectivity of the interlayer insulating film II2 is different from that of the metal interconnects AL1, downward etching of the interlayer insulating film II2 can be easily ended at a point where the metal interconnect AL1 is reached.

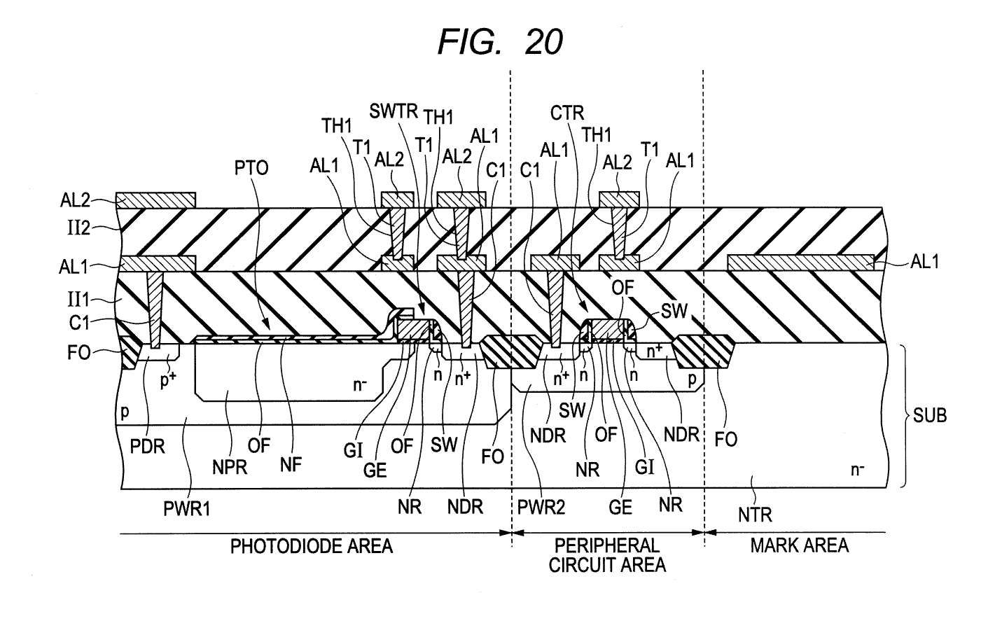

Referring to FIG. 20, a conductive layer T1, for example, made of tungsten is filled in each through hole TH1. Then, a pattern of metal interconnects AL2, for example, made of aluminum is made over the interlayer insulating film II2. The conductive layer T1 and metal interconnects AL2 are formed with the same procedure as the contacts C1 and metal interconnects AL1. No metal interconnects AL2 are formed in the mark area.

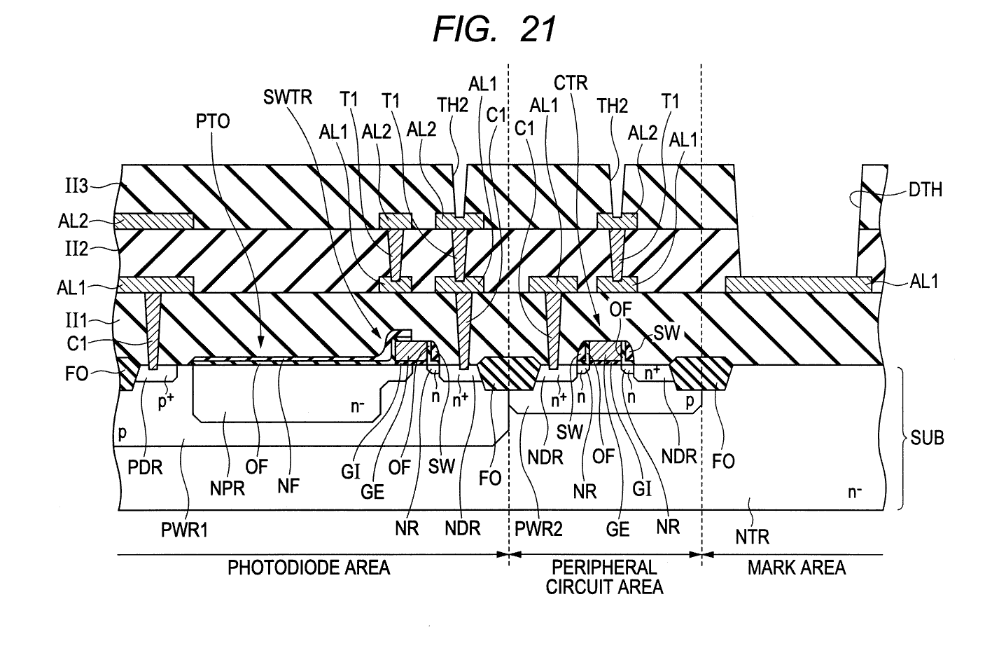

Referring to FIG. 21, an interlayer insulating film II3 is formed over the interlayer insulating film II2 and metal interconnects AL2 and through holes TH2 are made in desired places (above the metal interconnects AL2). The interlayer insulating film II3 and through holes TH2 are formed with the same procedure as the interlayer insulating film II2 and through holes TH1.

The through holes TH2 are formed in the photodiode and peripheral circuit areas in a way to reach the metal interconnects AL2 from the top of the interlayer insulating film II3. On the other hand, in the mark area the through hole DTH is formed in a way to reach the stopper film AL1 from the top of the interlayer insulating film II3. The through hole DTH is made by etching the interlayer insulating films II2 and II3 in a way to penetrate them. Since the etching selectivity of the interlayer insulating films II2 and II3 is different from that of the stopper film AL1, etching for the formation of the through hole DTH can be easily ended at a point where the stopper film AL1 is reached.

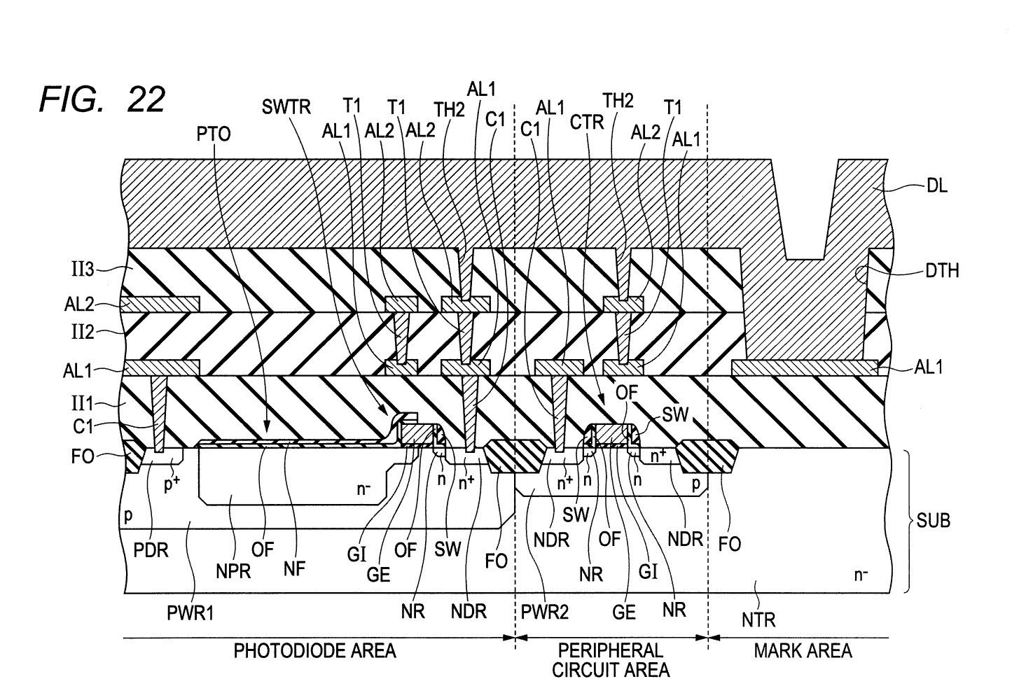

Referring to FIG. 22, a conductive film DL, for example, made of tungsten is formed over the interlayer insulating film II3 in a way to fill the through holes TH2 and through hole DTH. The diameter and depth of the through hole DTH are larger than the diameter and depth of the through holes TH2. Therefore, while the conductive film DL completely fills the through holes TH2, it does not fill the through hole DTH completely and stretches along the sidewall and bottom wall of the through hole DTH. After that, the conductive film DL is polished and removed by CMP until the upper surface of the interlayer insulating film II3 is exposed.

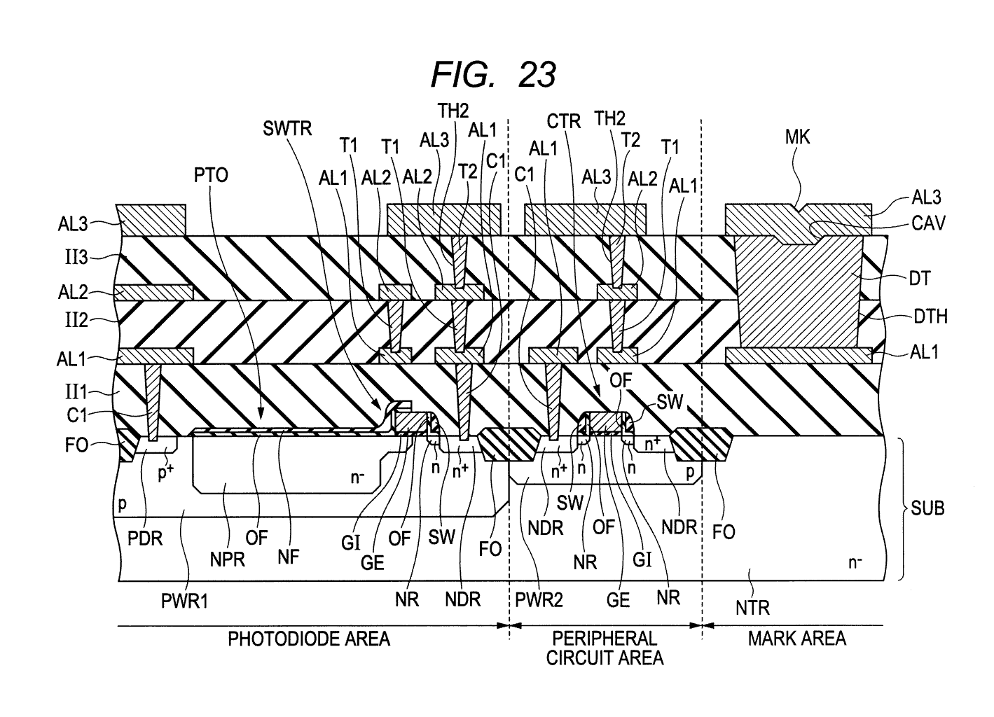

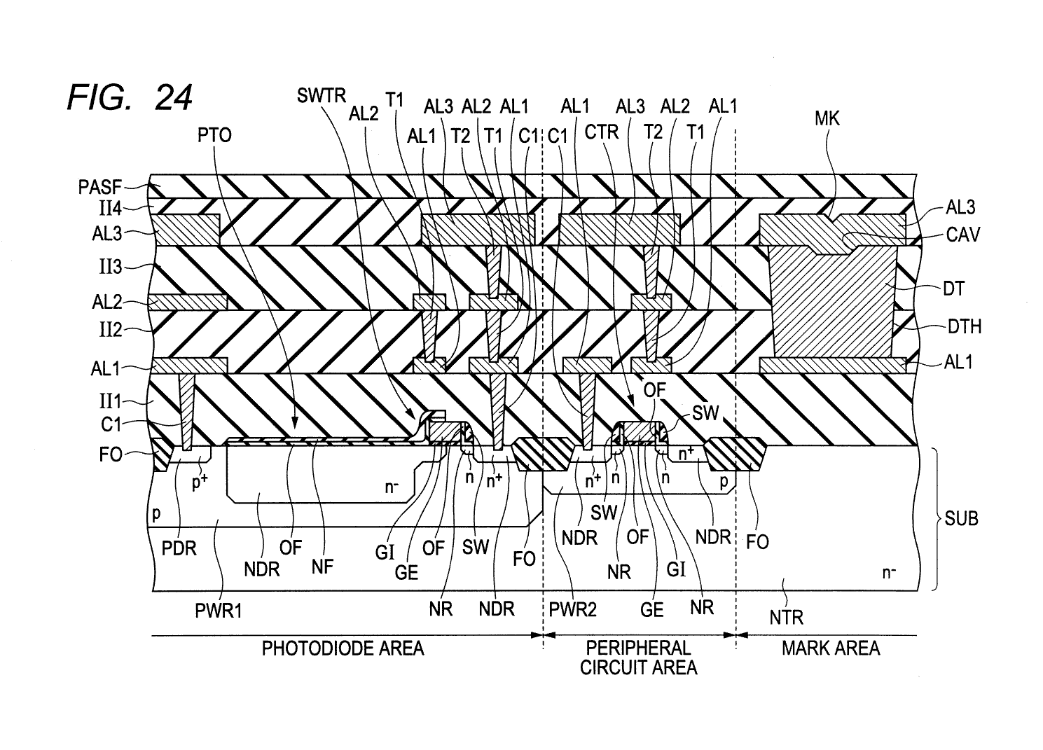

Referring to FIG. 23, as a result of the above CMP process, a conductive layer T2 is formed from the conductive film DL in the through holes TH2 and a conductive layer DT is formed from the conductive film DL in the through hole DTH. The conductive layer DT is formed along the sidewall and bottom wall of the through hole DTH with a concave CAV in its upper surface.

In the above film formation process, some portion of the conductive film DT filled in the through hole DTH does not reach the uppermost surface of the interlayer insulating film II3 in a plan view and that portion is shallower than the other surrounding portion. As a consequence, the concave CAV (first concave) is formed.

A metal film AL3 is formed in a way to cover the upper surfaces of the conductive layer DT, conductive layers T2, and interlayer insulating film II3. A concave (second concave) MK is made in the upper surface of the metal film AL3 just above the concave CAV. This concave MK is used as an alignment mark in positioning a photo mask (reticle) in the photoengraving process for patterning the metal film AL3.

Specifically, in the process of patterning the metal film AL3, photoresist (photoreceptor) is first coated on the metal film AL3. Then, after positioning the photo mask using the concave MK as an alignment mark, a prescribed portion of the photoresist is exposed to light transmitted through the photo mask. After that, the photoresist is developed and patterned into a prescribed shape. Using the patterned photoresist as a mask, the metal film AL3 is patterned into a prescribed shape by etching. Then, the photoresist is removed by asking or a similar technique.

As a result of patterning the metal film AL3, metal interconnects AL3 are formed from the metal film AL3 in the photodiode and peripheral circuit areas and the metal film AL3 for an alignment mark with the concave MK remains over the conductive layer DT in the mark area.

Referring to FIG. 24, an interlayer insulating film 114 is formed over the interlayer insulating film II3 in a way to cover the metal interconnects AL3 and the alignment mark metal film AL3. The upper surface of the interlayer insulating film 114 is flattened, for example, by CMP. After that, a silicon nitride film is deposited over the interlayer insulating film 114, for example, by CVD. This silicon nitride film becomes a passivation film PASF.

Lastly, a condenser lens LENS is placed just above the photodiode PTO and the image sensor as shown in FIG. 10 is thus completed.

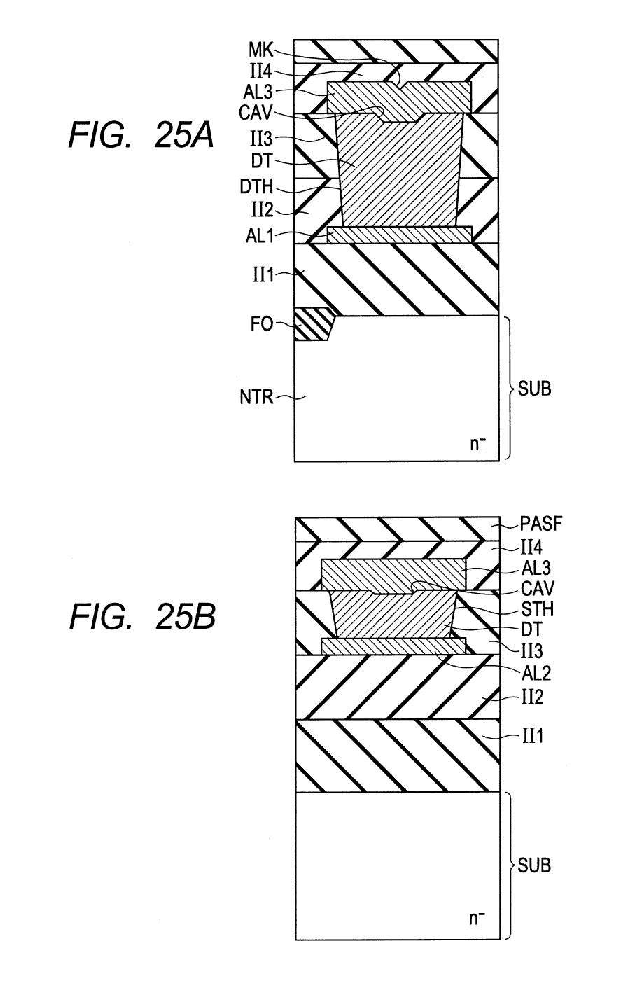

Next, the effect of this embodiment will be described referring to FIGS. 25A and 25B. FIG. 25A shows the structure of the mark area in this embodiment shown in FIG. 10. The through hole DTH penetrates the interlayer insulating films II2 and II3. FIG. 25B shows a comparative example in which a through hole STH penetrates only the interlayer insulating film II3. Since the comparative example shown in FIG. 25B is structurally the same as the first embodiment shown in FIG. 25A except that the through hole STH penetrates only the interlayer insulating film II3, the same elements are designated by the same reference numerals and their descriptions are omitted here.

A shallow hole like the through hole STH of the comparative example shown in FIG. 25B can be easily filled by the conductive layer DT. This means that a concave CAV is hardly produced in the upper surface of the conductive layer DT which fills the through hole STH. If there is no concave CAV in the upper surface of the conductive layer DT or the concave is small, a concave to serve as an alignment mark is not produced in the upper surface of the metal layer AL3 formed over the conductive layer DT. Also, even if a concave for an alignment mark is produced, it will be very small and not suitable for use as an alignment mark.

On the other hand, in the first embodiment shown in FIG. 25A, the through hole DTH is deeper, penetrating the two interlayer insulating films II2 and II3. Therefore, it is not easy to fill the through hole DTH completely by the conductive layer DT, making it more likely to produce a large (deep) concave CAV in the upper surface of the conductive layer DT. Thus, a large concave MK is easily produced in the upper surface of the metal film AL3 formed over the conductive layer DT. The large concave MK will serve as an alignment mark which ensures high alignment accuracy.

In this embodiment, since the depth of the through hole DTH corresponds to the combined thickness of the two interlayer insulating films, a deeper concave MK can be made than in the comparative example. Therefore, the intensity of light entering the photodiode PTO can be increased by decreasing the thicknesses of the interlayer insulating films II2 and II3 while keeping the required depth of the concave MK for use as an alignment mark.

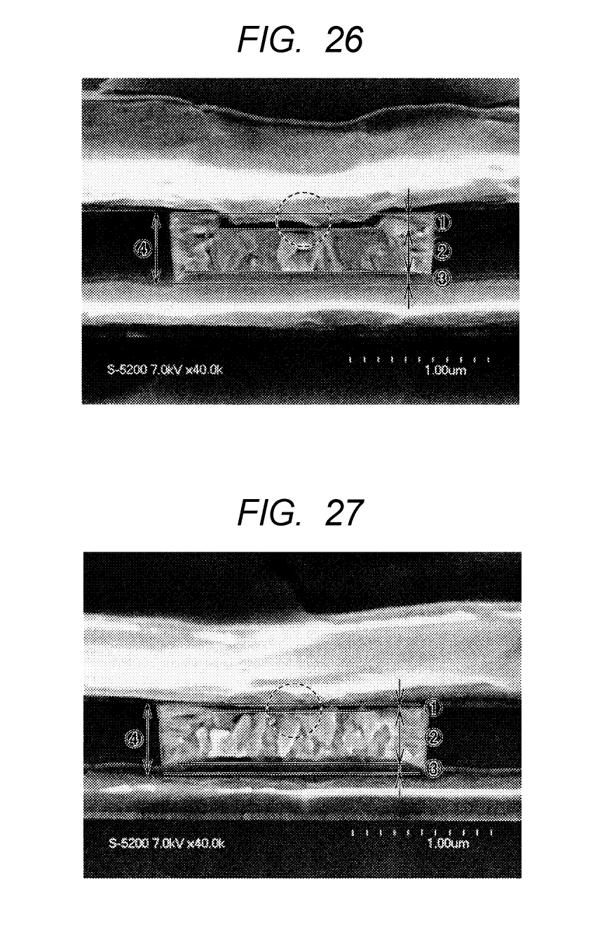

If a clear, deep concave MK is made, it will be easier to perform patterning using the concave MK as an alignment mark at a later step. This is explained below referring to FIGS. 26 and 27 and the table below.

TABLE 1

| | Suitable as an | Unsuitable as an |
|---|---|---|
| | alignment mark | alignment mark |
| (1) Mark depth | 125 nm | 12 nm |
| (2) Mark-to-barrier | 297 nm | 365 nm |
| metal distance | | |
| (3) Barrier metal | 93 nm | 80 nm |
| thickness | | |
| (4) Through hole | 515 nm | 457 nm |
| conductive layer | | |
| thickness | | |

The area encircled by dotted line in FIGS. 26 and 27 shows a concave MK. The dimensions represented by numbers 1 to 4 in FIGS. 26 and 27 correspond to the dimensional data for items (1) to (4) of Table 1 respectively. Dimensions related to a mark suitable for use as an alignment mark (FIG. 26) are shown in the “Suitable as an alignment mark” column of Table 1 and dimensions related to a mark unsuitable for use as an alignment mark (FIG. 27) are shown in the “Unsuitable as an alignment mark” column of Table 1.

The comparison shows that the mark suitable for use as an alignment mark is larger in depth and also larger in the overall thickness (4) of the conductive layer in the through hole than the mark unsuitable for use as an alignment mark.

Since all the films are not flattened by CMP, the sum of numerical data for items (1), (2) and (3) of Table 1 is not always equal to the numerical data for item (4).

Furthermore, in this embodiment, since the through hole DTH does not reach the surface of the semiconductor substrate SUB, variation in the radial thickness of the concave MK is small. Therefore, alignment accuracy is improved.

Furthermore, in this embodiment, the wall surface of the through hole DTH is a continuous surface extending from the upper surface of the interlayer insulating film II3 to the metal interconnect AL1 without any level difference in the boundary between the interlayer insulating films II2 and II3. This eliminates the possibility of variation in the radial thickness of the concave MK due to a level difference, ensuring high alignment accuracy.

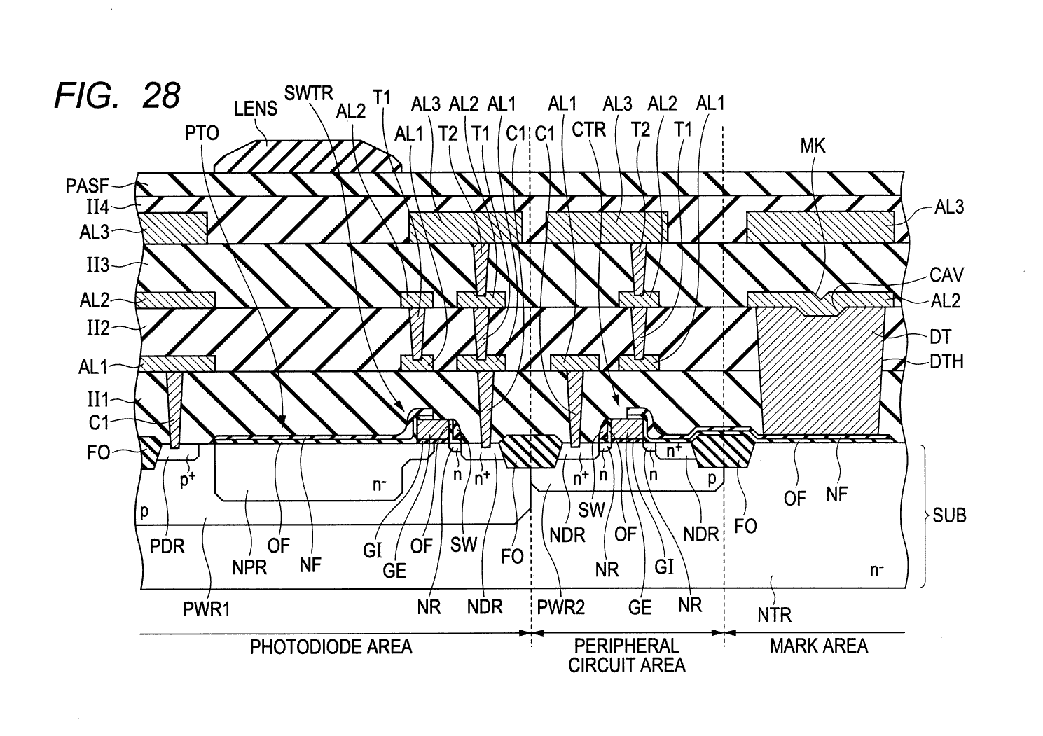

In the formation of the through hole DTH in the mark area as mentioned above, the stopper film AL1 is the first metal interconnect AL1. However, it is acceptable that the stopper film in the formation of the through hole DTH is the same silicon nitride film. NF as used for the anti-reflection coating in the photodiode PTO as shown in FIG. 28. This is because the silicon nitride film, the upper film of the anti-reflection coating, has a high etching selectivity with respect to an interlayer insulating film (silicon oxide film, etc).

The image sensor shown in FIG. 28 is different from the image sensor shown in FIG. 10 in terms of the stopper film in the mark area and the layer in which the mark is made. In the structure shown in FIG. 28, the stopper film in the mark area is the silicon nitride film NF of the anti-reflection coating as mentioned above. The layer in which the concave MK is made is the metal film AL2 formed separately using the second metal interconnect AL2. Since the image sensor shown in FIG. 28 is almost the same as the image sensor shown in FIG. 10 except the abovementioned, the same elements in FIG. 28 as those in FIG. 10 are designated by the same reference numerals and their descriptions are omitted here.

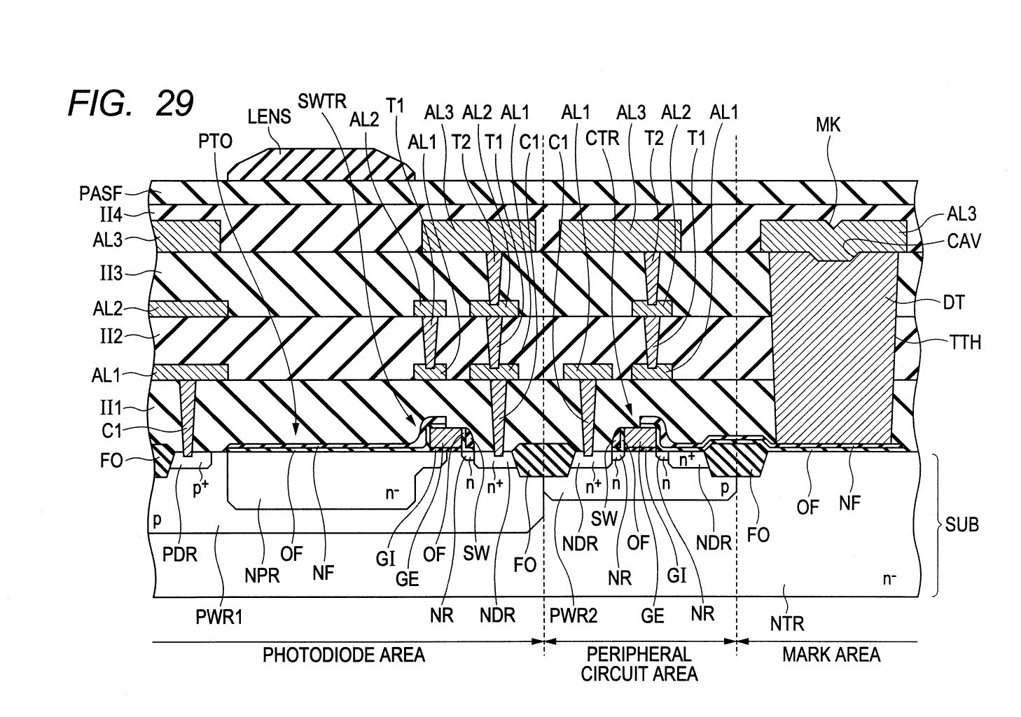

The stopper film in the image sensor shown in FIG. 28 is formed separately using the silicon nitride film NF of the photodiode PTO. Therefore, the stopper film is located under the interlayer insulating film II1, so the level of the top of the through hole DTH is almost equal to the level of the top of the interlayer insulating film II2. However, it is also acceptable that as shown in FIG. 29, the level of the top of the through hole TTH is almost equal to the level of the top of the interlayer insulating film II3 like the structure shown in FIG. 10. In that case, the through hole TTH penetrates three layers, namely interlayer insulating films II1, II2, and II3.

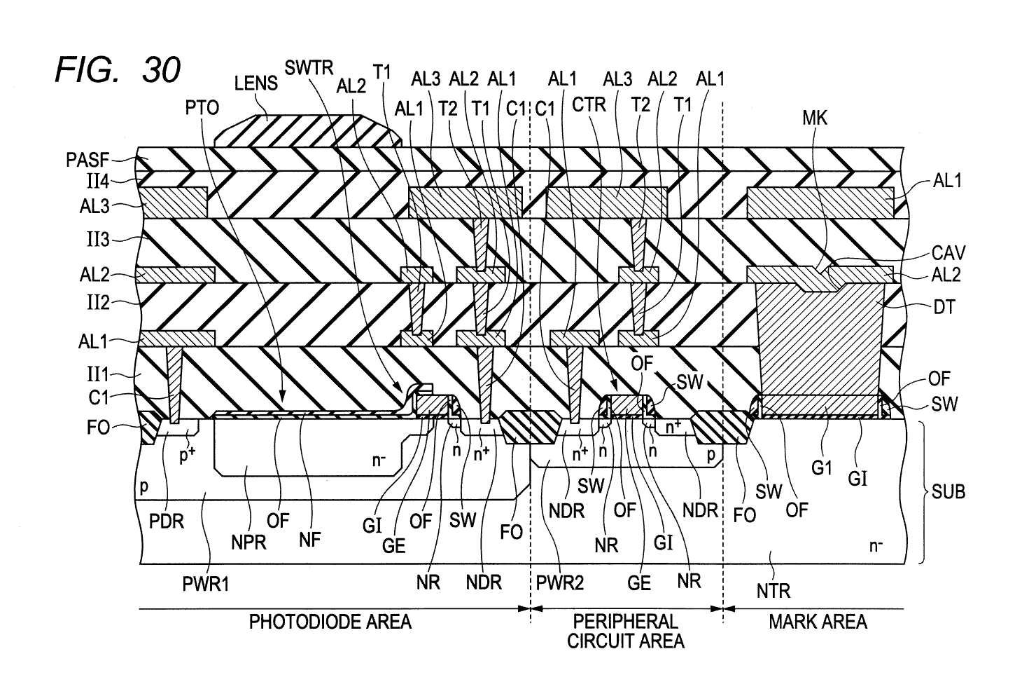

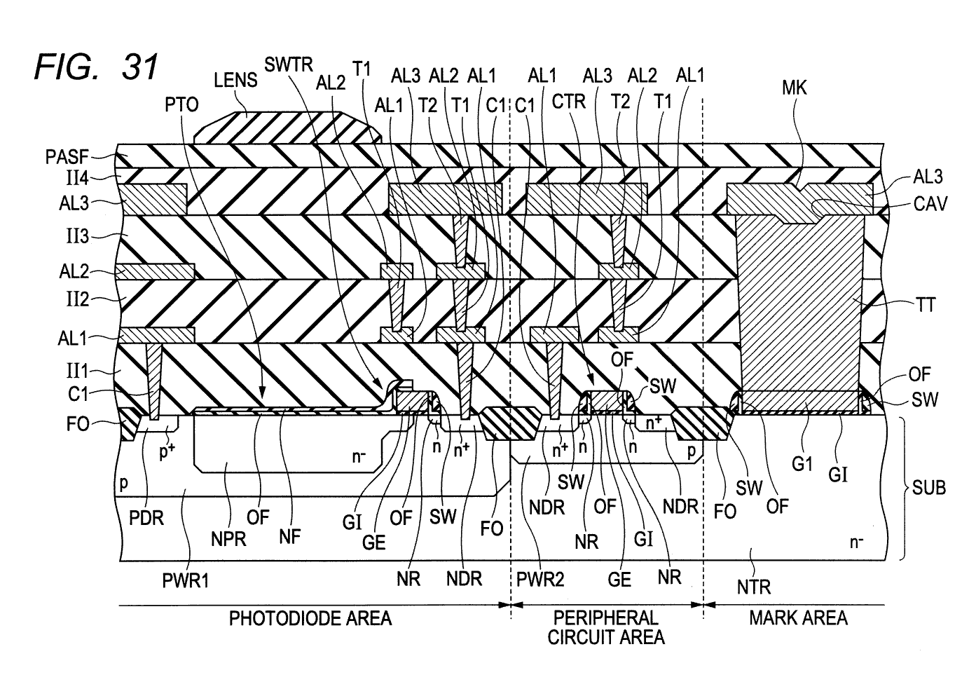

As another example, it is acceptable that as shown in FIG. 30, the stopper film is a thin film of polycrystal silicon which is the same material as that of the gate electrodes GE of the control transistor CTR and switching element SWTR. This is because polycrystal silicon has a high etching selectivity with respect to an interlayer insulating film (silicon oxide film, etc). The image sensor shown in FIG. 30 is almost the same as the image sensor shown in FIG. 10 except the above-mentioned.

The stopper film G1 in the image sensor shown in FIG. 30 is separately formed using the same layer as used for the gate electrodes GE of the control transistor CTR and switching element SWTR. Therefore, the stopper film is located under the interlayer insulating film II1, so the level of the top of the through hole DTH is almost equal to the level of the top of the interlayer insulating film II2. However, it is also acceptable that as shown in FIG. 31, the level of the top of the through hole TTH is almost equal to the level of the top of the interlayer insulating film II3 like the structure shown in FIG. 10. In that case, the through hole TTH penetrates three layers, namely interlayer insulating films II1, II2, and II3.

### Second Embodiment

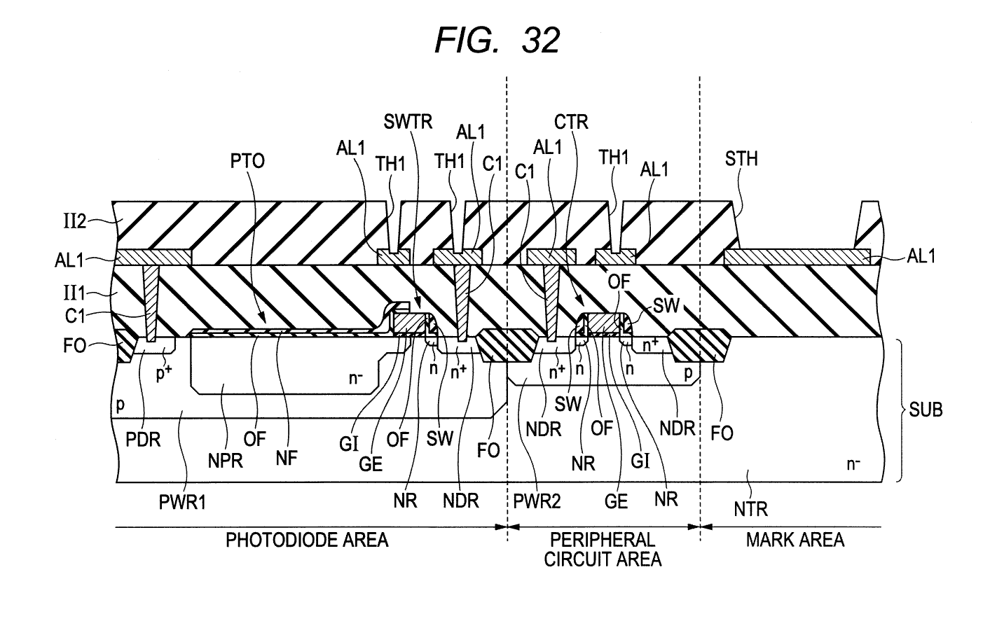

The second embodiment is different from the first embodiment in the method for making a concave MK. Next, the method for manufacturing a semiconductor device (image sensor) according to the second embodiment will be described referring to FIGS. 32 to 36.

In the second embodiment, the same steps as those shown in FIGS. 11 to 18 in the first embodiment are taken. Specifically, a photodiode PTO is formed inside the semiconductor substrate SUB and metal interconnects AL1 and a stopper film AL1 are formed over the main surface of the semiconductor substrate SUB.

The step shown in FIG. 32 is different from the step shown in FIG. 19 in the first embodiment in that a through hole STH is made in the mark area too. In other words, the through hole STH which penetrates the interlayer insulating film II2 is made with the metal film AL1 in the mark area as the stopper film.

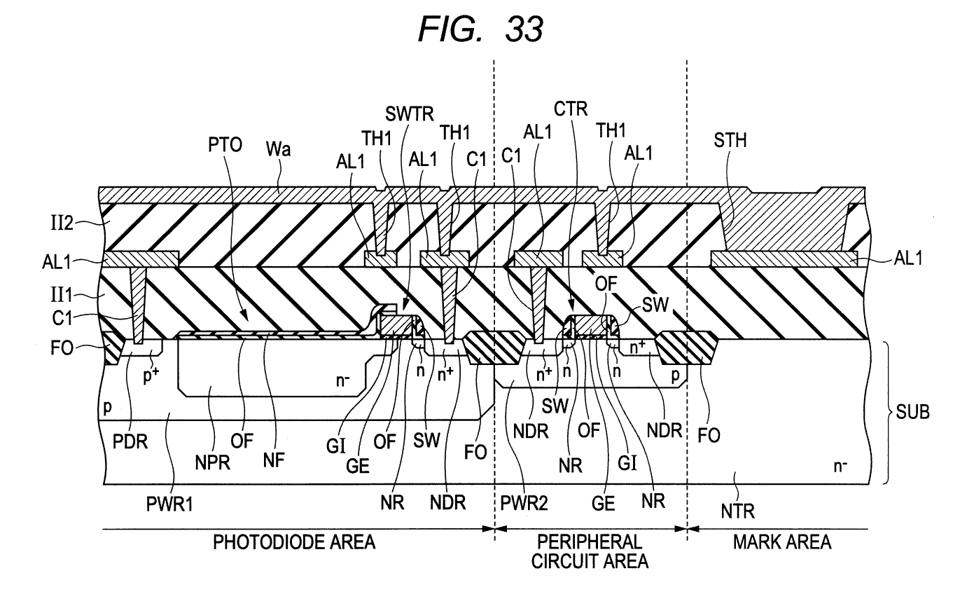

Referring to FIG. 33, a conductive film Wa, for example, made of tungsten is formed over the interlayer insulating film II2 in a way to fill the through holes TH1 and through hole STH. The conductive film Wa is formed, for example, by CVD. After that, the conductive film Wa is polished and removed by CMP until the upper surface of the interlayer insulating film II3 is exposed.

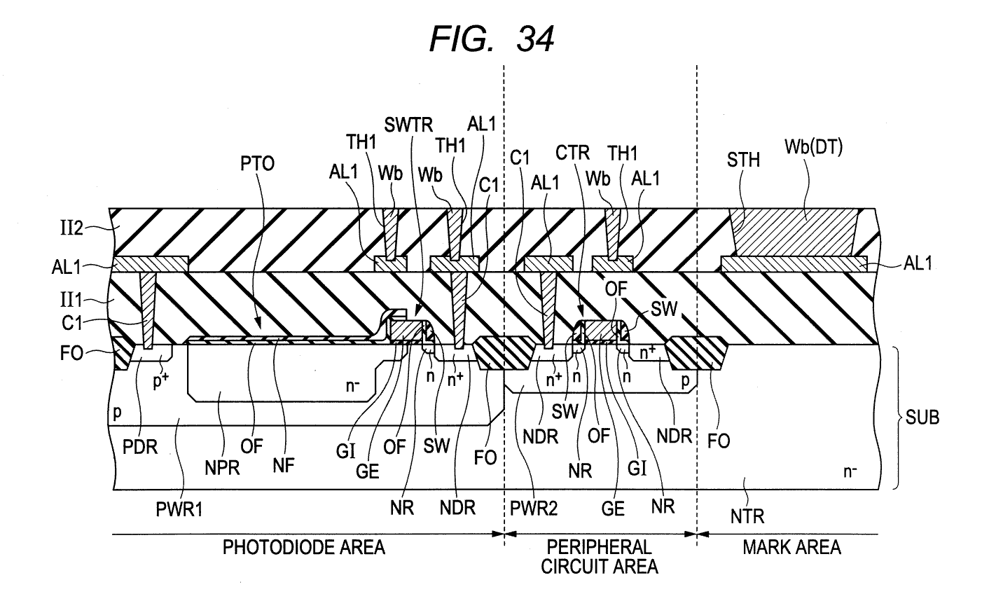

Referring to FIG. 34, as a result of the above CMP process, the conductive film Wa made of tungsten in the through holes TH1 and STH remains unremoved and becomes a conductive layer Wb. The upper surface of the conductive layer Wb which fills the through holes TH1 and STH is almost flattened.

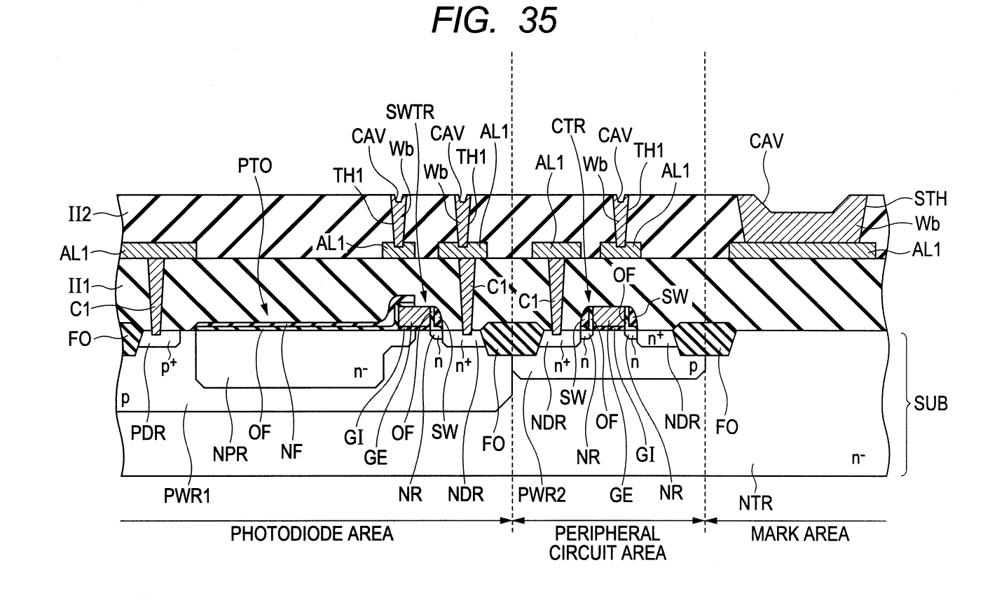

Referring to FIG. 35, some portions of the upper surface of the tungsten conductive layer Wb in the through holes TH1 and STH are selectively removed by an etch-back technique. In this process, the upper surface of the tungsten conductive layer Wb is recessed downward with respect to the upper surface of the interlayer insulating film II2, thereby producing a concave CAV in the upper surface of the tungsten conductive layer Wb.

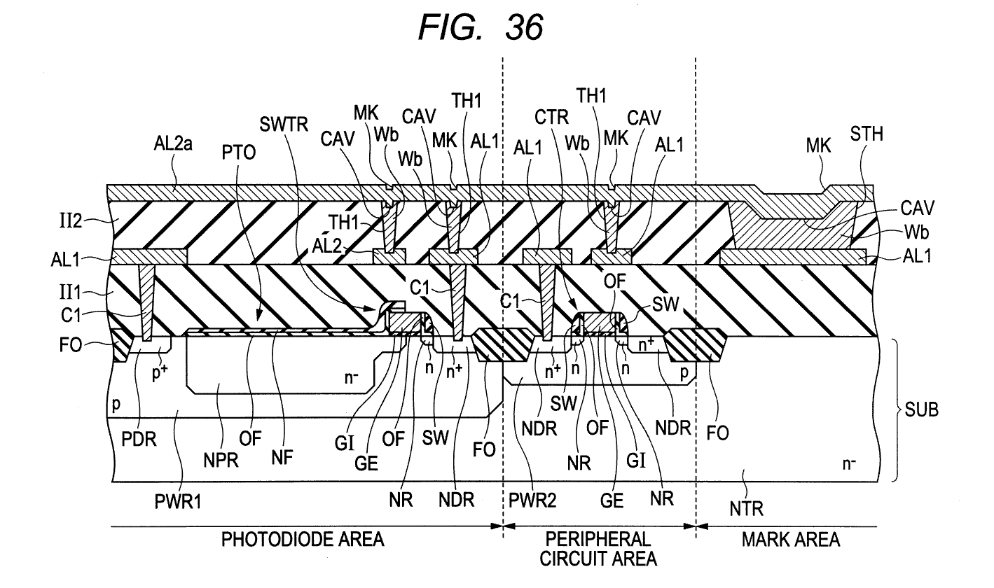

Referring to FIG. 36, a thin metal filmAL2a (metal layer), for example, made of aluminum is formed over the interlayer insulating film II2 and tungsten conductive layer Wb, for example, by sputtering. At this time, a concave MK to serve as an alignment mark is made in the upper surface of the thin metal film AL2a just above the concave CAV of the conductive layer Wb in the through hole STH. Subsequently the thin metal film AL2a is patterned using ordinary photoengraving and etching techniques to form metal interconnects, though not shown.

In pattering the thin metal film AL2a, positioning (alignment) of the photo mask is performed using the concaves MK made in the thin metal film AL2a as alignment marks. Patterning of the thin metal film AL2a is performed almost in the same way as pattering of the metal film AL3 in the first embodiment.

After that, an interlayer insulating film II3 and so on are formed as in the first embodiment and finally the image sensor is completed.

As shown in FIGS. 32 to 36, the image sensor in the second embodiment is almost the same as the image sensor in the first embodiment except the abovementioned, so in FIGS. 32 to 36, the same elements as those in the first embodiment are designated by the same reference numerals and their descriptions are omitted here.

Next the effect of the second embodiment will be described.

If a conductive layer Wb is formed in the through hole STH made in the single interlayer insulating film II2 as mentioned above and the conductive layer DT (Wb) in the mark area is thin, a concave CAV may not be produced in the upper surface of the conductive layer Wb. This is because a shallow hole like the through hole STH of the comparative example shown in FIG. 25B can be easily filled by the conductive layer DT.

In this embodiment, the upper surface of the conductive layer Wb is selectively removed by an etch-back technique as shown in FIGS. 34 and 35. Consequently, the upper surface of the conductive layer Wb is recessed with respect to the upper surface of the interlayer insulating film II2, thereby producing a concave CAV in the upper surface of the conductive layer Wb. The concave CAV for an alignment mark is thus made in the upper surface of the conductive layer Wb in the through hole STH, which suggests that it is possible to make a sufficiently deep concave CAV for an alignment mark in the upper surface of the conductive layer Wb in the through hole STH made in the single interlayer insulating film II2. Therefore, it is possible to improve the photosensitivity of the photodiode PTO by decreasing the thickness of the interlayer insulating film over the photodiode PTO and ensure high alignment accuracy.

FIGS. 32 to 36 show a case that the conductive layer DT (Wb) in the through hole STH is etched back. However, for example, even when the conductive layers in the contact holes and through holes made in the interlayer insulating films II1 and II3 are similarly etched back, a similar effect can be achieved. Furthermore, the conductive layer DT or TT shown in FIG. 29 or 31 may be etched back similarly. Furthermore, the stopper film for the conductive layer DT (TT) in the mark area is not limited to a metal interconnect made of aluminum but it may be a silicon nitride film NF formed separately using the same layer as used for the anti-reflection coating shown in FIGS. 28 and 29 or a thin film formed separately using the same layer as used for the gate electrodes shown in FIGS. 30 and 31.

In addition, in this embodiment, it is desirable to use an ordinary CVD technique (vapor growth method without sputtering during deposition) to form the conductive film Wa which fills the through hole STH. In some cases, a film which fills a hole in this way is formed by the vapor growth method called HDP (High Density Plasma)-CVD in which deposition and sputtering are performed simultaneously by applying a bias RF (Radio Frequency) to the wafer. In this method, the sidewall of the concave MK in the upper surface of the conductive film Wa hardly becomes perpendicular to the main surface of the semiconductor substrate SUB. Specifically, the sidewall of the concave MK becomes gradually narrower in the depth direction from the upper surface of the conductive film Wa and becomes triangular in a sectional view. As a result, the profile of the concave MK is unclear, so the concave MK as an alignment mark cannot ensure high alignment accuracy.

On the other hand, when the through hole STH is filled by the conductive film Wa by the vapor growth method without sputtering during deposition, the sidewall of the concave MK in the upper surface of the conductive film Wa can be made perpendicular to the main surface of the semiconductor substrate SUB. As a result, the profile of the concave MK is clear, so the concave MK as an alignment mark can ensure high alignment accuracy.

The second embodiment of the invention is different from the first embodiment only in the abovementioned points. In other words, the second embodiment is the same as the first embodiment in all other points such as structure, conditions, procedure and effect.

It should be considered that the embodiments disclosed herein are illustrative in all aspects and not restrictive. The scope of the present invention is defined by the appended claims rather than by the description preceding them, and all changes that fall within metes and bounds of the claims, or equivalence of such metes and bounds are therefore intended to be embraced by the claims.

The present invention can be used effectively for a semiconductor device having a photoelectric transducer and a method for manufacturing the same.

What is claimed is:

1. A semiconductor device comprising:
a semiconductor substrate having a main surface;
a photoelectric transducer formed in the semiconductor substrate;
a stopper film formed over the main surface of the semiconductor substrate;
a first interlayer insulating film formed over the stopper film and over the photoelectric transducer;
a first metal interconnect formed over the first interlayer insulating film;
a second interlayer insulating film formed so as to cover the first metal interconnect and the photoelectric transducer, with a hole made in the first and second interlayer insulating films, penetrating the first and second interlayer insulating films and reaching the stopper film;
an in-hole conductive layer formed along a sidewall and a bottom wall of the hole with a first concave in an upper surface thereof; and
a second metal interconnect formed over the in-hole conductive layer and the second interlayer insulating film, with a second concave to serve as an alignment mark, located just above the first concave and in an upper surface thereof.

2. The semiconductor device according to claim 1,
wherein the sidewall of the hole forms a continuous surface in a direction from an upper surface of the second interlayer insulating film to the stopper film without any level difference in a boundary between the first interlayer insulating film and the second interlayer insulating film.

3. The semiconductor device according to claim 1 or 2,
wherein the stopper film is made of a material which is different in etching selectivity from the first and second interlayer insulating films.

4. The semiconductor device according to any of claims 1 to 3,
wherein the stopper film is a third metal interconnect formed in a layer under the first metal interconnect.

5. The semiconductor device according to any of claims 1 to 3,
wherein the stopper film is a film formed separately using the same layer as used for an anti-reflection coating of the photoelectric transducer.

6. The semiconductor device according to any of claims 1 to 3,
wherein the stopper film is formed separately using the same layer as used for a transistor gate electrode.

7. A method for manufacturing a semiconductor device comprising the steps of:
forming a photoelectric transducer in a semiconductor substrate having a main surface;
forming a metal interconnect over the main surface of the semiconductor substrate;
forming an interlayer insulating film over the metal interconnect and over the photoelectric transducer;
making, in the interlayer insulating film, a hole reaching the metal interconnect;
forming a conductive layer for filling the hole;
removing an upper surface of the conductive layer selectively to make the upper surface of the conductive layer recessed from an upper surface of the interlayer insulating film; and
forming a metal layer over the upper surface of the conductive layer and over the upper surface of the interlayer insulating film so as to make a concave to serve as an alignment mark, in an upper surface of the metal layer just above the conductive layer.

8. The method for manufacturing a semiconductor device according to claim 7,
wherein the step of forming a conductive layer for filling the hole includes:
a step of forming the conductive layer so as to fill the hole and cover the interlayer insulating film; and
a step of polishing and removing the conductive layer by a chemical mechanical polishing method until the upper surface of the interlayer insulating film is exposed.

9. The method for manufacturing a semiconductor device according to claim 8,
wherein the conductive layer is formed by a vapor growth method without sputtering during formation of the film.
